(19) United States
(12) Patent Application Publication
(10) Pub. No.: US 2008/0218755 A1
(43) Pub. Date: Sep. 11, 2008

(54) SEMICONDUCTOR UV ABSORPTIVE PHOTOMETRIC CELLS

(75) Inventor: Bohumil Lojek, Colorado Springs, CO (US)

Correspondence Address: SCHWEGMAN, LUNDBERG & WOESSNER / ATMEL, P.O. BOX 2938, MINNEAPOLIS, MN, 55402, US

(73) Assignee: ATMEL CORPORATION, San Jose, CA (US)

(21) Appl. No.: 11/683,623

(22) Filed: Mar. 8, 2007

(51) Int. Cl. G01N 21/00; H01L 31/113

(52) U.S. Cl. 356/432; 257/294; 257/E31.084

(57) ABSTRACT

Biomolecules in solid or liquid form are targeted with a UV beam of about 260 nm that is attenuated by absorption in the biomolecules. The attenuated light passes through a UV transmissive window and partly discharges an underlying floating gate EPROM device. The incremental partial discharge of the floating gate device alters the threshold voltage of the device and is read by an analog output amplifier. Variation in threshold voltage of the device is measured with respect to the extent of optical absorption by the biomolecules resulting in photometric data. A biomolecule target array can be fabricated as an X-Y array in a chip or wafer over an array of correspondingly spaced EPROM devices with control devices forming cells with each cell separately readable.

### TECHNICAL FIELD

The invention relates to semiconductor integrated circuit electro-optical photometric devices for measuring properties of biomolecules, such as nucleic acids, and other targets.

### BACKGROUND

There is presently a need to rapidly analyze large numbers of compounds, particularly biomolecules. For example, the completion of sequencing of the human genome has provided very numerous targets to analyze and investigate. Advances in combinatorial chemistry allows generation of very large numbers of target compounds to analyze.

Optical photometric analysis provides a high throughput mean to analyze large numbers of compounds, such as biomolecules. Regarding use of semiconductors for high throughput analysis, some have sought to use integrated circuit technology to rapidly detect properties of large numbers of biomolecules in arrays.

An EPROM is a type of non-volatile semiconductor memory chip normally operated as a digital device. Non-volatile means that the chip retains information when power is removed. One class of EPROM devices is erasable with erasing performed by directing ultraviolet (UV) light through a quartz or boron silicate glass window toward a floating gate of the EPROM device. Data in the form of electronic charge is stored on a floating gate electrode that is programmed by manipulation of transistor electrodes to charge the device for one digital state and erased with strong UV light, typically in the range of 225 nm-275 nm, for the second digital state.

A need exists for an inexpensive sensor for measuring targets, such as biomolecules for example, in large arrays.

### SUMMARY

It has been discovered that the same UV wavelengths that are effective for photometric analysis of biomolecules and the like are also effective for electron transfer in floating gate devices, i.e. removing charge by incrementally erasing the devices. This has led to fabricating a UV photometric sensor with higher sensitivity than hereto possible because the device is very sensitive to a narrow UV wavelength band and other wavelengths are self-rejected. The UV photometric sensor is a type of charge storage device, preferably a floating gate EPROM transistor having a variable threshold voltage that can act in place of a photometer.

A UV photometric sensor array of the present invention may be used to analyze an array of biomolecule sites on a carrier. The sites have biomolecules that are responsive to UV light for determining a biomolecule property. The sites, supported on a carrier, are transmissive of UV light that is partly attenuated by interaction with the biomolecules. Receiving the attenuated light is an array of non-volatile, individually addressable cells of charge storage devices, such as EPROM transistors, that start out fully charged. Thus, the UV photometric sensor array includes the biomolecule sites, the non-volatile addressable cells separated from the UV photometric sensor array by a UV window with a UV light source used to direct light to the array of biomolecule sites. Upon impingement of UV light, the biomolecule sites attenuate the UV light in proportion to a known characteristic property of the biomolecules. The attenuated light is transmitted through the window, which is transparent in the UV spectral region, to the non-volatile cells of charge storage devices. The charge storage cells are incrementally discharged or erased in proportion to the amount of UV light absorbed. An analog output amplifier is configured to read a relative change in threshold voltage in each charge storage cell that results from the incremental discharge of the cell, with an output indicating to the extent of absorbed UV light. The UV light transmissive window that separates the biomolecule sites from the addressable charged cells is in a sandwich configuration in which the biomolecule site array, the window and the UV sensor array are in close contact. The addressable aspect of the charged cells allows individual cells to be selected and read for a charge value which is translated to a determination of the biomolecule property.

Because EPROM floating gate transistor devices can be integrated in a chip or wafer, it is possible to combine microarrays of biomolecule sites with a corresponding array of EPROM devices in an overlay relation. Because EPROM floating gate devices have also been constructed with X-Y address circuitry, one can read each UV photometric sensor individually.

To review, UV light is directed from a UV specific source through the microarray of molecules for detection of phenomena that would have UV absorption as an indicator. As mentioned, the charge storage devices are preferably of the EPROM type, namely having a UV transmissive window receiving UV light that has been attenuated to some extent by interaction with biomolecules in a well or an array. UV transmissive windows are those that transmit UV light in a passband relatively well compared to other wavelengths that are suppressed or rejected. Here the passband is approximately 225 nm-275 nm. The UV light source may be integrated into the UV photometric sensor array or may be external and separated from the UV photometric sensor array. In an EPROM, the UV light causes incremental erasing of the floating gate, i.e. the transfer of holes from the floating gate to a substrate in a non-volatile or permanent manner in proportion to the amount of incident UV light. A charge storage capacitor would work similarly. The electrical charge state of the floating gate influences the conduction ability of an associated transistor by a property known as the threshold voltage, V_{T}, that can be read by an analog output amplifier, such as a difference amplifier. It has been found that the change in threshold voltage an be almost linearly related to UV attenuation. Because both the biomolecules and the EPROM are sensitive to UV light centered at 260 nm, the measurements are more sensitive and selective than if made with broadband detectors, such as CCD elements of photodiodes or other photodetectors. The EPROM window acts as a filter, suppressing light of wavelengths not of interest.

The EPROM device of the present invention features a central poly floating gate that is surrounded laterally by a control gate that has a subsurface electrode that is shared with an adjacent control transistor so that each EPROM device can be individually addressed. A layer of quartz, borosilicate glass or other appropriate material provides UV transmissive window separating the EPROM array from the biomolecule array, but the EPROM array, the window and the biomolecule array are all sandwiched together in close proximity. Light is directed through the biomolecule array, through the UV window and onto the EPROM array where changes in threshold voltage of each cell can be measured in a predetermined sequence. The change in threshold voltage of each EPROM is a photometric measurement of the incremental charge removed from the EPROM by attenuated UV light and a direct measure of light removed in a corresponding biomolecule site, thereby indicating in an analog output amplifier a biomolecule property by translation from a prior calibration.

### BRIEF DESCRIPTION OF THE DRAWINGS

FIG. 1 is a plan perspective view of a first embodiment of a UV absorption array in accordance with the present invention.

FIG. 2 is a plan perspective view of a second embodiment of a UV absorption array in accordance with the present invention.

FIG. 3 is a top view of a single semiconductor data storage cell for use in devices of FIGS. 1 and 2.

FIG. 4 is a side sectional view taken along lines A-A in FIG. 3.

FIG. 5 is an electrical schematic for the data storage cell of FIG. 3.

FIG. 6 is a plot of threshold voltage for a single semiconductor data storage cell as shown in FIG. 3 versus optical absorption.

### DESCRIPTION OF INVENTION

With reference to FIG. 1 the UV photometric sensor array 10 is seen to have two major components. The first is an array 11 of variable threshold devices set up as transistors of the EPROM type that are mounted in an integrated circuit chip 13. The device array 11 is thus an X-Y array of EPROM transistors as in a semiconductor memory, except not operated as digital devices, but as analog devices. Such an array contains addressing circuitry, power supply circuitry and data reading or sensing circuitry. The addressing circuitry has the capability of individually writing or reading a selected cell. A floating gate in each EPROM serves as a charge storage element for a photometric measuring system. Each EPROM transistor is charged by placing electronic charge, i.e. electrons or holes, on the floating gate. Impingement of UV light on the floating gate partly erases or removes charge from the floating gate by creation of a discharge path in silicon dioxide. UV light reaches the floating gate through a UV light transparent window 15 covering the floating gate, facing upwardly toward UV beam 25. The impingement of light coming through window 15 onto the floating gate can be the measure of absorption of light through an optical cell through which the UV light passes. The state of charge of the floating gate, i.e. the extent of discharge of the floating gate, is read by electronic circuitry, described below, with data emerging through chip pins 17 to outside data logging equipment.

Window 15 can be quartz or may be a borosilicate glass, preferably having the highest possible UV transmission in the range of 225-275 nm. One such suitable glass is described in U.S. Pat. No. 5,547,904 but many other suitable window materials are known. It is possible that the biomolecule carrier could serve as window 15 if made of appropriate material. In this situation the carrier is the UV window as well as being a biomolecule support.

Above the window 15 is a carrier 23 which may be an opaque material having an array of biomolecule sites 21 that are light transmissive. The biomolecule sites may be fluidic wells for holding small volumes of liquid target material or solid receptor sites for binding target molecules. There may be a one-to-one correspondence between biomolecule sites 21 and EPROM transistors in device array 11 of variable threshold transistors. The biomolecule sites have the property of attenuating UV light when target material is stimulated or intercepted by UV light. For example, optical absorbance at 260 nm is routinely used to measure concentration of nucleic acids in solution. This example illustrates a standard measurement of a spectrophotometer.

The present discovery allows a number of types of assays. For example, quantification of nucleic acids may occur by measuring light absorbed at 260 nm. Because single stranded DNA and double stranded DNA have different absorption characteristics at 260 nm, this allows a simplified assay of DNA hybridization. This allows determination of complementary strands of DNA without use of any additional dye or label, as the double stranded DNA is self reporting. In another type of assay, the purity of DNA could be analyzed. Pure double stranded DNA has (at 50 μg/ml) an absorbance at 260 nm of 1.0 and that the ratio of absorbance at 260 and 280 nm of the sample will be greater than 1.8. If the sample has an A260/A280 of less than 1.8, the sample is probably contaminated with protein. In the present methods, the samples could be placed in microplate wells and the wells of a microplate could be sequentially illuminated with 260 nm and 280 nm illumination and absorbance could be sequentially illuminated at each wavelength. Between illuminations the sensor (once read and date logged) could be reset.

Larger targets could also be used. These include cellular assays, beads or other particulate targets. For example, certain pathological cells are characterized by UV absorption changes. A tissue section on a slide could be illuminated with UV light as a whole and pathological cells responsive to UV light localized and enumerated in a single analysis event. The slide must be registered or indexed to the UV sensor array such that X-Y positions on the slide correspond to known UV detector locations. The device could also be used for screening materials for UV absorbance/reflection properties for possible use as skin protection, window coatings or other uses. These are just a few illustrations of the uses of the present devices. The present invention allows for nearly simultaneous measurements as many thousands of sites where biomolecular or other targets reside at this same wavelength.

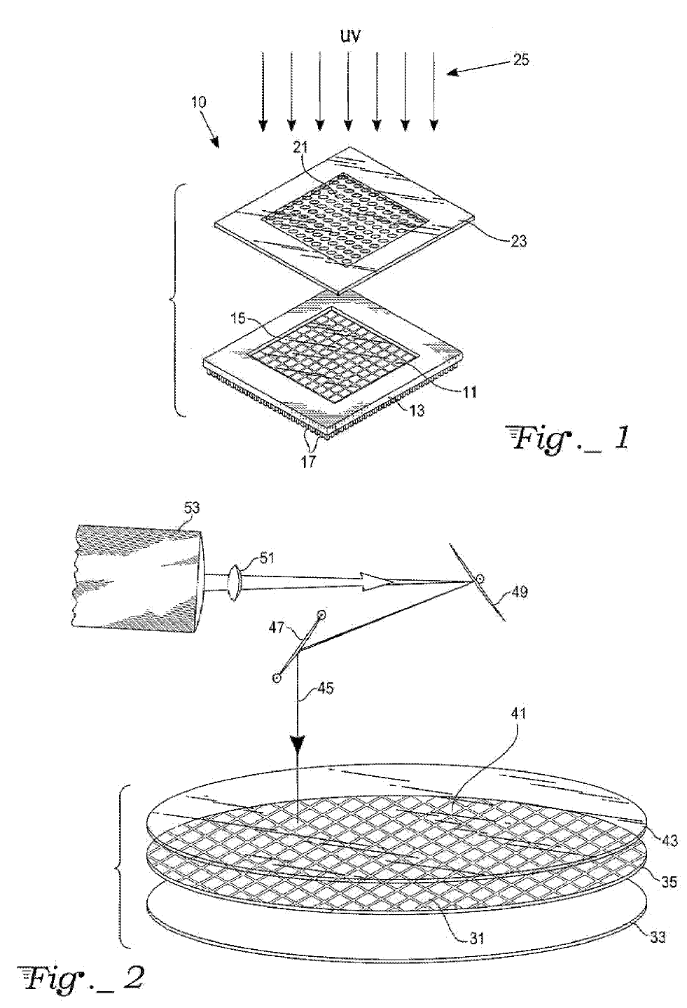

In operation, an IC chip with an array of EPROM transistors would be all programmed or fully charged with electrons on the floating gates. This is done with electrical circuitry by injection of charge from a substrate doped region to the floating gate. The window 15 is blocked with an opaque screen to prevent accidental erasing by ambient light or else the window 15 is kept dark. The chip is overlaid with the array of biomolecule sites in registration with the EPROMs using robotic electromechanical techniques. The opaque screen is removed and biomolecule target sites are illuminated with UV light which is attenuated or absorbed by the biomolecules in relation to a measured parameter. In this illustration, the sites are sufficiently separated so that illumination through one site affects only one EPROM transistor. Each EPROM transistor is incrementally erased, i.e. charge removed from the floating gate in proportion to the UV impinging on the floating gate. This is the amount of light from the UV source less the amount of light attenuated by the biomolecule sample and less the light lost in the window. The latter quantity is the same for all EPROMs and can be ignored. Impinging light is pulsed at a known rate so that the amount of illumination for samples can be quantified and reproduced. The charge that is removed may be either holes or electrons depending on whether an NMOS or PMOS EPROM design is used. In a PMOS transistor, holes are the majority carriers and so holes will supply the maximum charge to the floating gate. For either NMOS or PMOS transistors, the role of UV light is the same, i.e. to incrementally remove charge from the floating gate. UV light creates electron-hole pairs in silicon dioxide, the insulating material between the floating gate and the substrate, thereby providing a discharge path for the charged floating gate. Although the silicon dioxide beneath the floating gate might be shielded from UV, there are sufficient electron-hole pairs crated near the edges of the floating gate to provide a discharge path. By targeting a floating gate with a beam, as in FIG. 2, the beam spot is larger than the floating gate area so that surrounding silicon dioxide is illuminated. The incrementally removed charge changes the threshold voltage of the EPROM transistor and the change in threshold voltage is read by an analog output amplifier.

With reference to FIG. 2, an array of variable threshold EPROM transistors 31 is fabricated as a semiconductor memory on wafer 33, together with ancillary circuitry, including address, read and write circuits. The memory is arranged in a grid of X-Y memory cells, with all cells having the same size. The memory array is covered with a thin sheet of quartz or borosilicate glass or other material, perhaps 0.1 to 1 mm thick as a UV window with the highest transmission in the 225-275 nm range, acting as a UV window 35. Atop the window 35 is a carrier 43 having an array 41 of biomolecule sites. The sites may be micro-wells in a glass plate holding liquid biomolecule target samples. The wells are transparent but surrounding glass is made opaque by masking. The substrate, wall bottom, or other biomolecule support preferably has similar UV transmission as the window, providing minimal interference with the UV measurements. Alternatively, the biomolecule sites may be solid receptor sites where target biomolecules are held in place, using probes or other receptors. The sites have the same dimension as a beam spot of an illuminating UV laser beam 45. The beam is steered to a desired X-Y location by scan mirrors 47 and 49 that are controlled by stepper motors and servos to go to a desired target location. A pulsed UV laser 53 directs a beam 45 through one or more lenses 51 toward the desired biomolecule site of the array 41 on carrier 43. In passing through the biomolecule site, UV light is attenuated in the same manner as described above, with the attenuated light being detected in a cell of the UV photometric sensor array. Once a reading is made in one UV photometric sensor cell, the beam is stepped using the scan mirrors 47 and 49 to the next biomolecule site and the process is repeated. Before receiving attenuated light, a corresponding UV photometric sensor cell must be fully charged because the attenuated light causes discharge of the UV photometric sensor cell in proportion to the amount received in accordance with a known relation that is established by calibration.

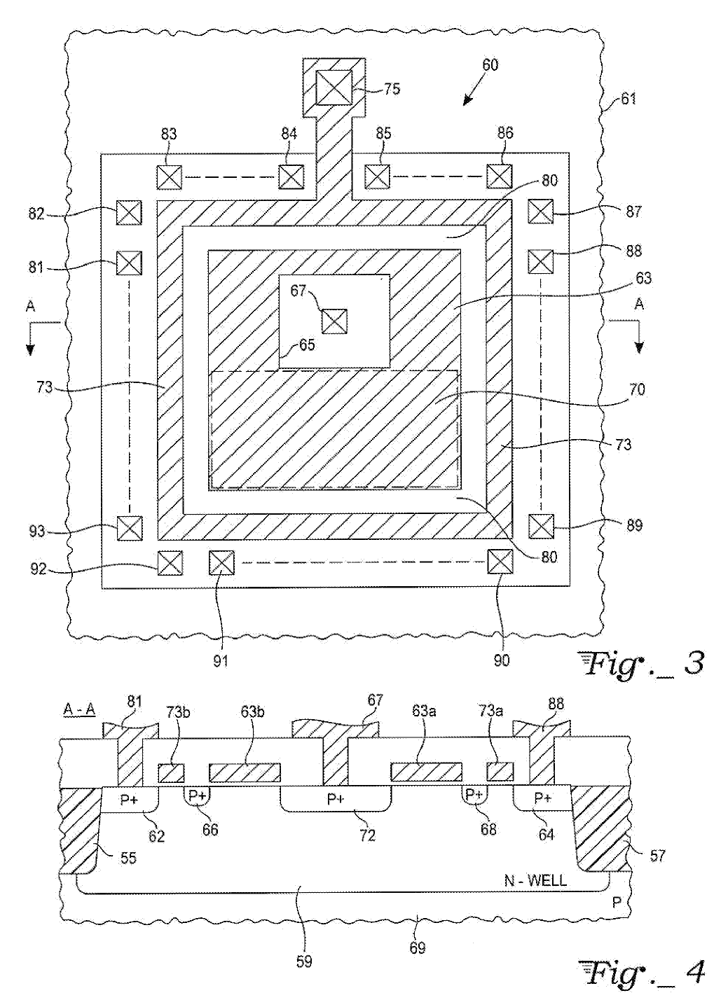

With reference to FIG. 3, a two-transistor UV photometric sensor cell is built on a semiconductor substrate 61, typically a silicon wafer. The cell is part of an X-Y array of cells arranged in an X-Y pattern like a semiconductor memory, or can be a stand alone device for disposable applications. A stand alone device may be a single cell. Ancillary memory circuits, such as address and read-write circuitry, are also included. Some arrays may be packaged as chips, shown in FIG. 1, or used in wafer form as shown in FIG. 2. In either situation the UV photometric sensor cell exists below a UV transmissive window, not shown. The window may be masked to prevent crosstalk from a neighboring cell in a manner so that only a rectangular sensing area 70, having a boundary indicated by a dashed line, is exposed to attenuated UV light. The central shaded zone is floating gate 63, a conductive polysilicon layer separated from the substrate 61 by an insulative layer, typically oxide. The floating gate 63 belongs to an EPROM transistor having subsurface source-drain electrodes and controlled by a control transistor. Floating gate 63 has a rectangular aperture 65 that accommodates a metal contact 67 that extends from above the floating gate 63 to substrate 61 where it makes contact with a subsurface electrode. The sensing area 70 is an integral and unitary part of floating gate 63, except that portions of floating gate 63 on sides of aperture 65 are masked off. Floating gate 63 is separated from the edge of the isolation region to prevent charge leakage between the floating gate and the isolation region.

Surrounding floating gate 63 is a channel 80 and a polysilicon control gate 73 belonging to a control transistor. The control gate has a loop shape except for a panhandle region 74 that extends beyond the active area of the cell where a metal contact 75 extends from above and contacts the control gate 73. The height of contact 75 is similar to contact 67.

Surrounding control gate 73 are a plurality of peripheral electrode contacts 81, 82, 83-93 disposed in a spaced relation relative to control gate 73 from a level similar to contacts 67 and 75. A boundary 76 defines the extent of the active area of the cell. Shallow trench isolation around boundary 76 electrically isolates cell 60 from neighboring cells.

With reference to FIG. 4, the floating gate portions 63a and 63b are on either side of a central P+ implant region in N-well 59 in P-type wafer substrate 69, the implant serving as a non-shared subsurface electrode 72, having the overlying metal contact 67. The floating gate portions 63a and 63b are over a channel of the floating gate transistor between electrode 72 and source-drain implant regions 66 and 68 that form an opposite subsurface electrode that establish the channel directly below floating gate portions 63a and 63b and in the substrate.

Edges of the cell are established by shallow trench isolation regions 55 and 57 that extend in a rectangle defining the active region shown by boundary 76 in FIG. 3. Returning to FIG. 4, the subsurface implant regions 62 and 64 are in the outer periphery of the active region and are among a number of similar implants in the substrate beneath the peripheral electrode contacts 81, 82, 83-93. The source-drain implant regions 66, 68 are part of a group of implants that similarly extend in a loop between the floating ate 63 and the control gate 73 such that a source-drain electrode, such as an electrode established by implant region 66 is opposite a peripheral electrode, such as an electrode associated with implant region 62, to define a channel for the control gate, such as control gate region 73b. The same channel is established on the opposite side by an electrode established by implant region 64 defining a channel under control gate region 73a that terminates at an electrode established by implant region 68.

Thus, a surrounded transistor is seen, having control gate 73 and subsurface electrodes on all sides of gate plus the floating gate 63 with subsurface electrodes on all four sides of the floating gate. The electrode contacts 67, 81 and 88, as well as contact 75 of FIG. 3, allow proper bias to be applied to the transistor for various operations such as fully charging the floating gate transistor and reading the charge on the floating gate.

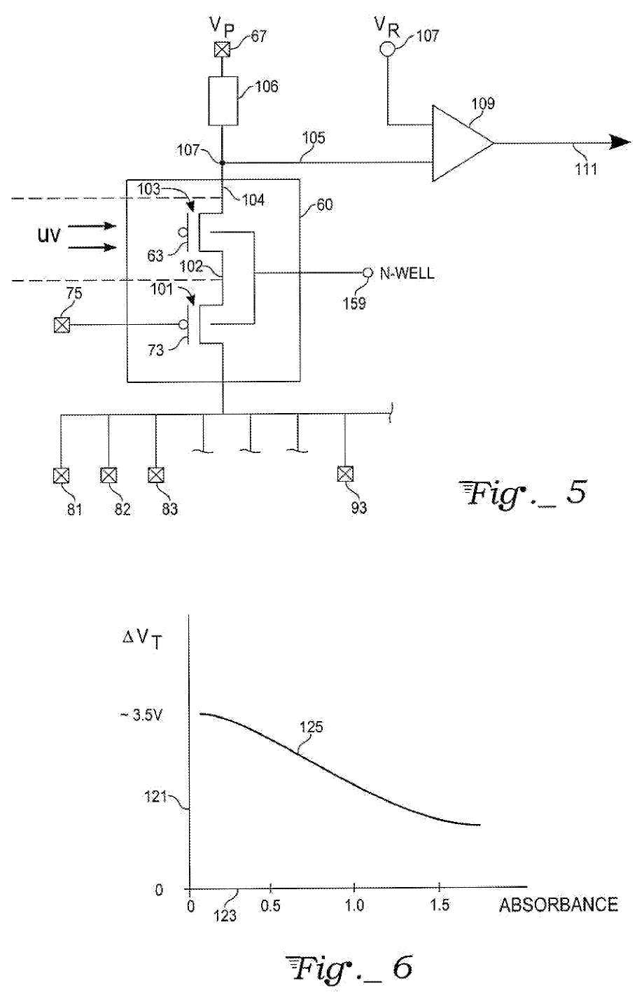

With reference to FIG. 5, the two PMOS transistor UV photometric sensor cell 60 having control transistor 101 has external contact 75 associated with control gate 73. Floating gate transistor 103 has a common source-drain electrode 102, corresponding to electrodes associated with implant regions 66, 68 in FIG. 4. Electrical ground is a peripheral electrode contact 81, corresponding to electrodes 81-93 in FIG. 3. The N-well is represented by a common potential at node 159, the N-well potential. The floating ate 63 has no contacts. An electrode 104 of the floating gate transistor 103 is connected to contact 67 where the programming potential V_{P} is applied. A voltage regulating device 106 assures that a desired voltage is not exceeded during charging of the floating gate. After the cell is charged, the programming potential is removed and the floating gate threshold voltage is read at node 107 when the control transistor 101 is selected by an appropriate read voltage applied at contact 75. The voltage on node 107 is transmitted on line 105 to difference amplifier 109, an analog output amplifier, that compares a reference voltage V_{R} from node 107 to the measured threshold voltage V_{T}. Difference amplifier 109 directly measures the changing threshold voltage, V_{T}, as erasing incremental occurs. When this voltage is plotted, a graph similar to FIG. 6 is observed. As described above, V_{T} changes in proportion to UV light absorbed by the UV photometric sensor cell.

With reference to FIG. 6, the vertical axis 121 shows the threshold voltage V_{T}, while the horizontal axis 123 shows light absorbance, an arbitrary scale of attenuated light from a UV source. The curve 125 is almost a linear relationship of plotted points showing how the threshold voltage of an EPROM cell varies with absorption of UV light in a calibrated cell. As more light is absorbed in the cell the threshold voltage of the EPROM decreases as charge is driven from the floating gate. In an array of cells, each cell is individually charged, illuminated with UV light, whether by a laser or a broad area source, and then read after discharge by light absorption. The output date is read and recorded and then the next cell is addressed. Each cell can be processed in an interval of about a hundred milliseconds, more or less.

While this patent application has described a semiconductor UV photometric sensor for use in analyzing biomolecules sensitive to UV light, other applications exist for the semiconductor UV photometric sensor. For example, in space applications, CMOS semiconductor integrated circuits can malfunction if exposed to UV radiation. The UV photometric sensor of the present invention could be used to shut down CMOS electronics upon detection of UV light that causes a predetermined shift in threshold voltage of the sensor. The window that transmits UV light to the photometric sensor may be used to attenuate UV light so that the characteristic curve of FIG. 6 is in the desired range for providing electronic safety based upon prior calibrations.

1. A UV photometric sensor comprising:
a non-volatile individually addressable EPROM charge storage transistor with a floating gate governing a variable threshold voltage indicative of stored charge and that is incrementally erasable by absorption of UV light directed toward the floating gate thereby varying the threshold voltage;
a window associated with each EPROM transistor transmitting UV light from a source, the UV light attenuated by a target before passing through the window;
an amplifier having an analog input signal connected to the individually addressed cell receiving a signal representing the variable threshold voltage as the analog input signal and having an output signal indicating absorbed UV light.

2. The apparatus of claim 1 wherein a plurality of said UV sensors are arranged in an array with an array of biomolecule sites directly over the UV sensor array, with a biomolecule site optically aligned with a UV sensor site, the biomolecule sites attenuating UV light.

3. The apparatus of claim 2 wherein the UV sensor array is a semiconductor chip or wafer.

4. A UV photometric sensor comprising:
a non-volatile, individually addressable cell of charge storage device that is incrementally erasable by absorption of UV light;
a biomolecule site on a carrier, the site being transmissive of attenuated UV light, the UV light being attenuated by biomolecule absorption in the site in relation to one or more biomolecule properties, the carrier site being optically aligned with said cell; and
a UV light transmissive window, rejecting other wavelengths, separating the charge storage cell device from the biomolecule site.

5. The UV photometric sensor of claim 4 arranged in an array with other such photometric sensors with a plurality of biomolecule sites also arranged in an array, the biomolecule sites optically aligned with the photometric sensors.

6. The UV photometric sensor of claim 5 wherein each charge storage device has a variable threshold characteristic at which conduction occurs between subsurface electrodes and has an associated amplifier with an input receiving the variable threshold characteristic and an output.

7. The UV photometric sensor of claim 5 wherein the charge storage devices are integrated in a semiconductor chip or wafer.

8. A UV photometric sensor comprising:
an array of non-volatile, individually addressable variable threshold transistors integrated upon a semiconductor substrate having windows transmissive of UV light, the thresholds of the transistors variable in a known manner with the extent of UV light impinging on the windows; and
an array of biomolecule sites directly over the array of transistors in an aligned relation, the sites attenuating UV light indicative of a biomolecule characteristics.

9. The UV photometric sensor of claim 8 further comprising a source of UV light impinging on at least one of the array of biomolecule sites, whereby attenuated UV light passes into a window where the threshold of a non-volatile variable threshold transistor is set to indicate the amount of attenuated light in a corresponding biomolecular site.

10. The UV photometric sensor of claim 8 wherein said array of integrated, non-volatile, individually addressable variable threshold transistors is a wafer or a chip.

11. The UV photometric sensor of claim 8 wherein said array of integrated, non-volatile, individually addressable variable threshold transistors is an array of floating gate cells.

12. The UV photometric sensor of claim 11 wherein each floating gate cell comprises an integrated floating gate device in series with a select device.

13. The UV photometric sensor of claim 12 wherein the floating gate device has a floating gate UV sensing area with a nearby window transmissive of UV light.

14. The UV photometric sensor of claim 12 wherein said floating gate sensing area is peripherally surrounded by a control gate of the select device.

15. A method for sensing biomolecules comprising:
directing UV light through target sites wherein target properties attenuate UV light;
directing the attenuated UV light onto charged charge storage devices of the type that remove charge in relation to incident UV light;
sensing the extent of charge removed in the charge storage devices; and
translating the sensed charge removed in the charge storage devices to associated biomolecule properties.

16. The method of claim 15 wherein the sensing of the extent of charge removed in charge storage devices is by measuring a change in threshold voltage of the charge storage devices.

17. The method of claim 15 further defined by placing biomolecules at the target sites.

18. The method of claim 15 further defined by placing DNA at the target sites.

19. The method of claim 15 further defined by placing microplate wells at the target sites.

20. The method of claim 15 further defined by placing tissue on a slide at the target sites.
